(19) United States
(12) Patent Application Publication
(10) Pub. No.: US 2024/0291428 A1
(43) Pub. Date: Aug. 29, 2024

(54) PHOTOVOLTAIC MODULES WITH ENERGY STORAGE COMPONENTS

(71) Applicant: GAF Energy LLC, Parsippany, NJ (US)

(72) Inventors: Richard Perkins, San Jose, CA (US); Hasib Amin, Parsippany, NJ (US)

(21) Appl. No.: 18/583,580

(22) Filed: Feb. 21, 2024

Related U.S. Application Data
(60) Provisional application No. 63/487,450, filed on Feb. 28, 2023.
(60) Provisional application No. 63/580,871, filed on Sep. 6, 2023.

(51) Int. Cl. H02S 40/38; H01L 31/049; H02S 20/23

(52) U.S. Cl. CPC H02S 40/38; H01L 31/049; H02S 20/23

(57) ABSTRACT

A system includes a plurality of photovoltaic modules installed on a roof deck. Each of the photovoltaic modules includes at least one solar cell, an encapsulant encapsulating the at least one solar cell, a frontsheet, a backsheet, a headlap portion, and an energy storage device between the roof deck and the backsheet. The energy storage device is in electrical communication with the at least one solar cell.

### CROSS-REFERENCE TO RELATED APPLICATION

This application is a Section 111(a) application relating to and claiming the benefit of commonly-owned, co-pending U.S. Provisional Patent Application Ser. No. 63/487,450, filed Feb. 28, 2023, entitled “PHOTOVOLTAIC MODULES WITH ENERGY STORAGE COMPONENTS;” and U.S. Provisional Patent Application Ser. No. 63/580,871, filed Sep. 6, 2023, entitled “PHOTOVOLTAIC MODULES WITH ENERGY STORAGE COMPONENTS;” the contents of each of which are incorporated herein by reference in its entirety.

### FIELD OF THE INVENTION

The present invention relates to photovoltaic systems and, more particularly, photovoltaic modules with energy storage components.

### BACKGROUND

Photovoltaic systems are installed on building roofs to generate electricity.

### SUMMARY

In some embodiments, a system includes a plurality of photovoltaic modules installed on a roof deck, wherein each of the photovoltaic modules includes at least one solar cell, an encapsulant encapsulating the at least one solar cell, wherein the encapsulant includes a first surface and a second surface opposite the first surface, a frontsheet juxtaposed with the first surface of the encapsulant, a backsheet juxtaposed with the second surface of the encapsulant, a headlap portion, wherein the photovoltaic module is installed on the roof deck by at least one fastener through the headlap portion, and an energy storage device between the roof deck and the backsheet, wherein the energy storage device is in electrical communication with the at least one solar cell.

In some embodiments, the energy storage device comprises a battery. In some embodiments, the energy storage device comprises a capacitor. In some embodiments, each of the photovoltaic modules includes an electronics assembly electrically communicating the at least one solar cell with the energy storage device. In some embodiments, the electronics assembly is on a lower surface of the backsheet. In some embodiments, the electronics assembly is on an upper surface of the backsheet. In some embodiments, each of the photovoltaic modules includes a side lap, wherein the side lap includes an upper surface, and wherein the electronics assembly is on the upper surface of the side lap. In some embodiments, the energy storage device is on a lower surface of the backsheet. In some embodiments, the electronics assembly comprises a controller configured to control at least one of charging of the energy storage device and discharging of the energy storage device. In some embodiments, the energy storage device has a thickness of 0.2 mm to 10 mm. In some embodiments, the at least one fastener includes a plurality of fasteners.

In some embodiments, the plurality of fasteners includes one or more of nails, rivets, staples and screws. In some embodiments, the headlap portion includes a nail zone, and wherein the plurality of fasteners is installed through the nail zone. In some embodiments, the energy storage device is disposed outside of the nail zone. In some embodiments, each of the plurality of photovoltaic modules does not include a frame.

In some embodiments, a photovoltaic module includes at least one solar cell; an encapsulant encapsulating the at least one solar cell, wherein the encapsulant includes a first surface and a second surface opposite the first surface; a frontsheet juxtaposed with the first surface of the encapsulant; a backsheet juxtaposed with the second surface of the encapsulant; a headlap portion; wherein the photovoltaic module is configured to be installed on a roof deck by at least one fastener through the headlap portion; and an energy storage device, wherein the energy storage device is below the backsheet, and wherein the energy storage device is in electrical communication with the at least one solar cell.

In some embodiments, the energy storage device comprises a battery. In some embodiments, the energy storage device comprises a capacitor. In some embodiments, the energy storage device is attached to a bottom surface of the backsheet. In some embodiments, the photovoltaic module includes an electronics assembly electrically communicating the at least one solar cell with the energy storage device. In some embodiments, the electronics assembly is on a bottom surface of the backsheet. In some embodiments, the electronics assembly is on a top surface of the backsheet. In some embodiments, the headlap portion includes a nail zone, and wherein the photovoltaic module is configured to receive the at least one fastener through the nail zone. In some embodiments, the energy storage device is disposed outside of the nail zone. In some embodiments, the photovoltaic module does not include a frame.

In some embodiments, a method comprises the steps of: obtaining a plurality of photovoltaic modules, wherein each of the photovoltaic modules includes at least one solar cell, an encapsulant encapsulating the at least one solar cell, wherein the encapsulant includes a first surface and a second surface opposite the first surface, a frontsheet juxtaposed with the first surface of the encapsulant, a backsheet juxtaposed with the second surface of the encapsulant, and a headlap portion, and an energy storage device, wherein the energy storage device is located below the backsheet, wherein the energy storage device is in electrical communication with the at least one solar cell; and installing the photovoltaic modules on a roof deck, wherein each of the photovoltaic modules is installed on the roof deck with at least one fastener through the headlap portion, and wherein the energy storage device is between the roof deck and the backsheet.

### BRIEF DESCRIPTION OF THE DRAWINGS

This section refers to the drawings that form a part of this disclosure, and which illustrate some of the embodiments of structure, materials, and/or methods of the present invention described herein.

FIGS. 1A and 1B are a top plan view and a side elevational view, respectively, of some embodiments of a photovoltaic module;

FIGS. 2 and 3 are schematic views of some embodiments of a photovoltaic module;

FIG. 4 is a top perspective view of some embodiments of a photovoltaic system;

FIG. 5 is a cross-sectional schematic view of some embodiments of a photovoltaic module; and

FIG. 6 is a schematic view of some embodiments of a photovoltaic module installed on a roof deck.

### DETAILED DESCRIPTION

In addition to the benefits and improvements that the Specification discloses, other objects and advantages of that the Specification provides will become apparent from the following description taken in conjunction with the accompanying figures. Although the description discloses and describes detailed embodiments of the present disclosure, the disclosed embodiments are merely illustrative of the disclosure that may be embodied in various forms. In addition, each of the examples given regarding the various embodiments of the disclosure are intended to be illustrative, and not restrictive.

Throughout the specification and claims, the following terms take the meanings explicitly associated herein, unless the context clearly dictates otherwise. The phrases “in an embodiment,” “in some embodiments,” and any similar phrase, as used herein, do not necessarily refer to the same embodiment or embodiments, though the phrases may refer to the same embodiment or embodiments. Furthermore, the phrases “in another embodiment,” and any similar phrase, as used herein, do not necessarily refer to a different embodiment, although the phrases may refer to a different embodiment. All embodiments of the disclosure are intended to be combinable without departing from the scope or spirit of the disclosure.

As used herein, terms such as “comprising,” “including,” “having,” and any similar phrase, do not limit the scope of a specific claim to the materials or steps recited by the claim.

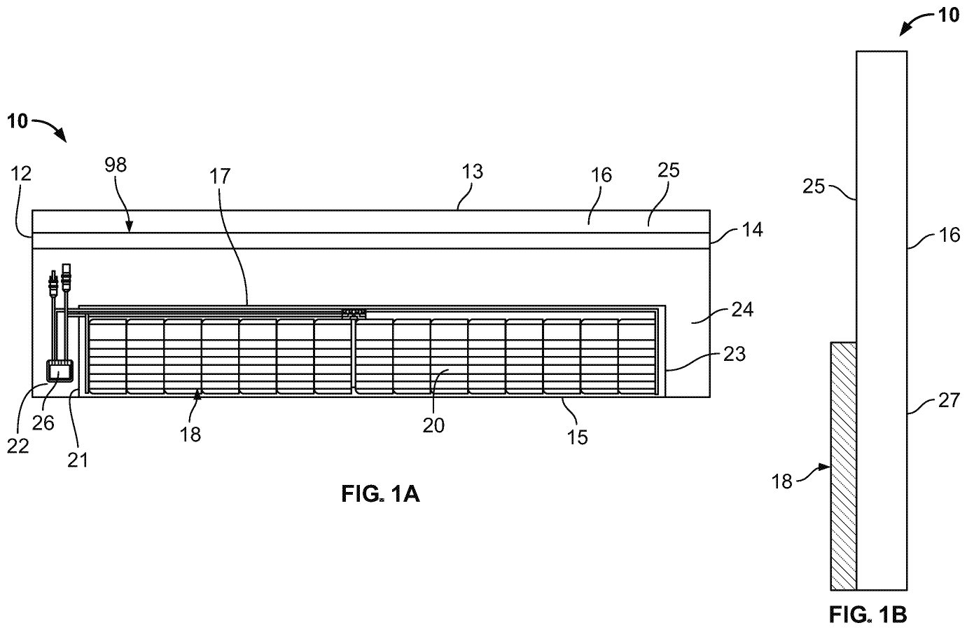

Referring to FIGS. 1A and 1B, in some embodiments, a photovoltaic module 10 includes a first end 12, a second end 14 opposite the first end 12, a first edge 13 extending from the first end 12 to the second end 14, and a second edge 15 opposite the first edge 13 and extending from the first end 12 to the second end 14. In some embodiments, the photovoltaic module 10 includes a headlap portion 16. In some embodiments, the headlap portion 16 extends from the first end 12 to the second end 14 and from the first edge 13 to a first location 17 between the first edge 13 and the second edge 15. In some embodiments, the photovoltaic module 10 includes a reveal portion 18. In some embodiments, the reveal portion 18 includes at least one solar cell 20. In some embodiments, the photovoltaic module 10 includes a first side lap 22 located at the first end 12. In some embodiments, the first side lap 22 includes a length extending from the first end 12 to a second location 21 between the first end 12 and the second end 14. In some embodiments, the photovoltaic module 10 includes a second side lap 24 located at the second end 14. In some embodiments, the second side lap 24 includes a length extending from the second end 14 to a third location 23 between the first end 12 and the second end 14. In some embodiments, the photovoltaic module 10 includes an outer surface 25 and an inner surface 27 opposite the outer surface 25. In some embodiments, the reveal portion 18 extends from the first side lap 22 to the second side lap 24 and from the second edge 15 to the first location 17. In some embodiments, the photovoltaic module 10 is configured to be installed on a building structure. In some embodiments, at least one junction box 26 is located on the first side lap 22. In some embodiments, the at least one junction box 26 includes a plurality of the junction boxes 26. In some embodiments, the photovoltaic module 10 includes a structure, composition, components, and/or function similar to those of one or more embodiments of the photovoltaic modules disclosed in PCT International Patent Publication No. WO 2022/051593, Application No. PCT/US2021/049017, published Mar. 10, 2022, entitled “Building Integrated Photovoltaic System,” owned by GAF Energy LLC, and U.S. Pat. No. 11,251,744 to Bunea et al., issued Feb. 15, 2022, entitled “Photovoltaic Shingles and Methods of Installing Same,” the contents of each of which are incorporated by reference herein in their entirety.

In some embodiments, the at least one solar cell 20 includes a plurality of the solar cells 20. In some embodiments, the plurality of solar cells 20 includes two solar cells. In some embodiments, the plurality of solar cells 20 includes three solar cells. In some embodiments, the plurality of solar cells 20 includes four solar cells. In some embodiments, the plurality of solar cells 20 includes five solar cells. In some embodiments, the plurality of solar cells 20 includes six solar cells. In some embodiments, the plurality of solar cells 20 includes seven solar cells. In some embodiments, the plurality of solar cells 20 includes eight solar cells. In some embodiments, the plurality of solar cells 20 includes nine solar cells. In some embodiments, the plurality of solar cells 20 includes ten solar cells. In some embodiments, the plurality of solar cells 20 includes eleven solar cells. In some embodiments, the plurality of solar cells 20 includes twelve solar cells. In some embodiments, the plurality of solar cells 20 includes thirteen solar cells. In some embodiments, the plurality of solar cells 20 includes fourteen solar cells. In some embodiments, the plurality of solar cells 20 includes fifteen solar cells. In some embodiments, the plurality of solar cells 20 includes sixteen solar cells. In some embodiments, the plurality of solar cells 20 includes more than sixteen solar cells.

In some embodiments, the plurality of solar cells 20 is arranged in one row (i.e., one reveal). In another embodiment, the plurality of solar cells 20 is arranged in two rows (i.e., two reveals). In another embodiment, the plurality of solar cells 20 is arranged in three rows (i.e., three reveals). In another embodiment, the plurality of solar cells 20 is arranged in four rows (i.e., four reveals). In another embodiment, the plurality of solar cells 20 is arranged in five rows (i.e., five reveals). In another embodiment, the plurality of solar cells 20 is arranged in six rows (i.e., six reveals). In other embodiments, the plurality of solar cells 20 is arranged in more than six rows. In some embodiments, the at least one solar cell 20 is electrically inactive (i.e., a “dummy” solar cell).

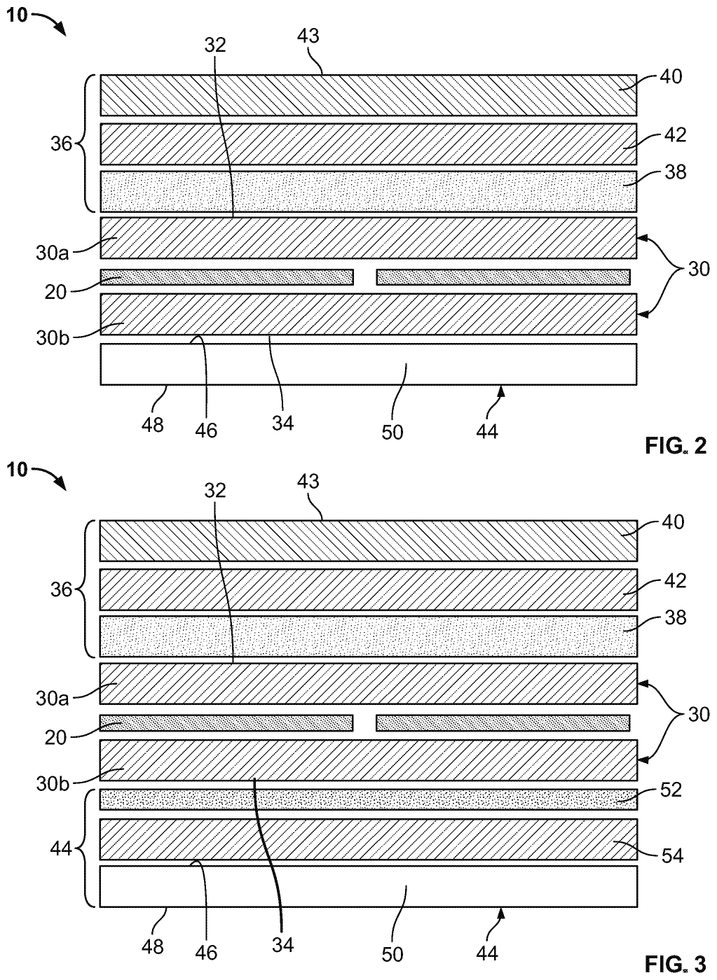

Referring to FIGS. 2 and 3, in some embodiments, the photovoltaic module 10 includes an encapsulant 30 encapsulating the at least one solar cell 20. In some embodiments, the encapsulant 30 includes a first layer 30a having a first surface 32 and a second layer 30b having a second surface 34 opposite the first surface 32. In some embodiments, the photovoltaic module 10 includes a frontsheet 36 juxtaposed with the first surface 32 of the first layer 30a of the encapsulant 30. In some embodiments, the frontsheet 36 includes a glass layer 38. In some embodiments, the frontsheet 36 includes a polymer layer 40 attached to the glass layer 38. In some embodiments, the polymer layer 40 forms an upper surface of the photovoltaic module 10. In some embodiments, the polymer layer 40 is attached to the glass layer 38 by a first adhesive layer 42. In some embodiments, an upper surface 43 of the polymer layer 40 is an upper surface of the photovoltaic module 10. In some embodiments, the upper surface 43 of the polymer layer 40 is textured. In some embodiments, the upper surface 43 of the polymer layer 40 is embossed. In some embodiments, the upper surface 43 of the polymer layer 40 is embossed with a plurality of indentations. In some embodiments, the upper surface 43 of the polymer layer 40 includes a pattern. In some embodiments, the upper surface 43 of the polymer layer 40 includes a printed pattern. In some embodiments, the upper surface 43 of the polymer layer 40 includes an embossed pattern. In some embodiments, the upper surface 43 of the polymer layer 40 includes a textured pattern.

In some embodiments, the photovoltaic module 10 includes a backsheet 44. In some embodiments, the backsheet 44 is juxtaposed with the second surface 34 of the second layer 30b of the encapsulant 30. In some embodiments, the backsheet 44 includes a first surface (top surface) 46 and a second surface (bottom surface) 48 opposite the first surface 46 of the backsheet 44. In some embodiments, the second surface 48 of the backsheet 44 forms a lower surface of the photovoltaic module 10. In some embodiments, the backsheet 44 includes a first layer 50. In some embodiments, the backsheet 44 includes a second layer 52 (see FIG. 3). In some embodiments, the second layer 52 is attached to the first layer 50 by a second adhesive layer 54. In some embodiments, the backsheet 44 includes only one layer (see FIG. 2). In some embodiments, the backsheet 44 includes only the first layer 50 (see FIG. 2). In some embodiments, the backsheet 44 does not include the second layer 52 (see FIG. 2). In some embodiments, the backsheet 44 is composed of a polymer. In some embodiments, the backsheet 44 is composed of thermoplastic polyolefin (TPO). In some embodiments, the backsheet 44 forms the headlap portion 16.

In some embodiments, each of the encapsulant 30, the frontsheet 36, including each of the glass layer 38, the polymer layer 40, and the first adhesive layer 42, and the backsheet 44, including the first layer 50, the second layer 52, and the second adhesive layer 54 of the photovoltaic module 10, as applicable, includes a structure, composition and/or function of similar to those of more or one of the embodiments of the corresponding components disclosed in PCT International Patent Publication No. WO 2022/051593, Application No. PCT/US2021/049017, published Mar. 10, 2022, entitled Building Integrated Photovoltaic System, owned by GAF Energy LLC, and U.S. Pat. No. 11,251,744 to Bunea et al., issued Feb. 15, 2022, entitled “Photovoltaic Shingles and Methods of Installing Same,” the contents of each of which are incorporated by reference herein in their entirety.

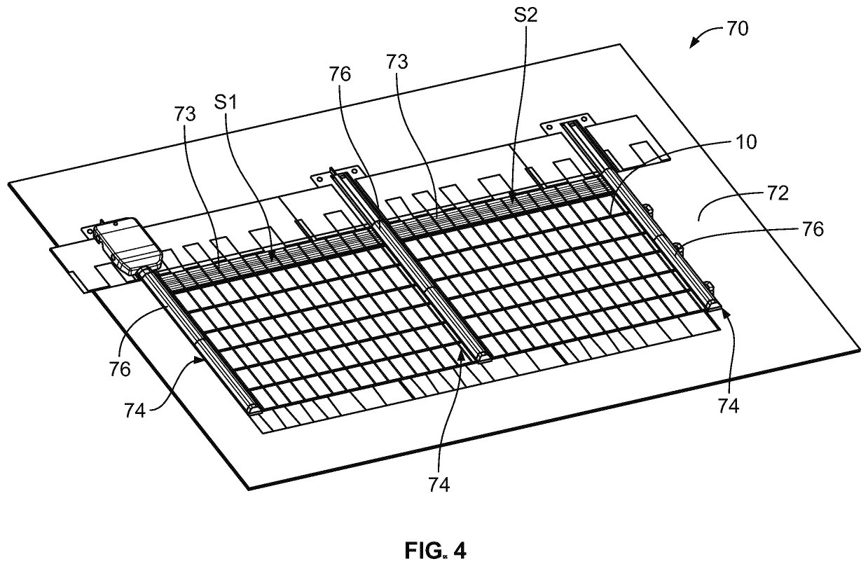

Referring to FIG. 4, in some embodiments, a system 70 includes a plurality of the photovoltaic modules 10 installed on a roof deck 72. In some embodiments, the plurality of the photovoltaic modules 10 is arranged in an array on the roof deck 72. In some embodiments, the array of the photovoltaic modules 10 includes subarrays S1, S2. In certain embodiments, the array includes more than the two subarrays S1, S2. In some embodiments, the array includes a single array S1. In some embodiments, each of the subarrays S1, S2 include a plurality of rows of the photovoltaic modules 10.

In some embodiments, the reveal portion 18 of one of the photovoltaic modules 10 in the subarray S1 overlays the head lap portion 16 of an adjacent another one of the photovoltaic modules 10 of the subarray S1. In some embodiments, at least a portion of the first side lap 22 of the one of the photovoltaic modules 10 overlays at least a portion of the first side lap 22 of the another one of the photovoltaic modules 10. In some embodiments, at least a portion of the second side lap 24 of the one of the photovoltaic modules 10 overlays at least a portion of the second side lap 24 of the another one of the photovoltaic modules 10.

In some embodiments, the first side lap 22 of one of the photovoltaic modules 10 in the subarray S2 overlays the second side lap 24 of an adjacent another one of the photovoltaic modules 10 in the subarray S1 in the same one of the rows R. In some embodiments, a jumper module 73 overlays an uppermost one of the photovoltaic modules 10 in a column of the subarray S1. In some embodiments, the active portion of the jumper module 73 overlays the head lap portion 16 of the photovoltaic module 10.

In some embodiments, the roof deck 72 is a steep slope roof deck. As defined herein, a “steep slope roof deck” is any roof deck that is disposed on a roof having a pitch of Y/X, where Y and X are in a ratio of 4:12 to 20:12, where Y corresponds to the “rise” of the roof, and where X corresponds to the “run” of the roof.

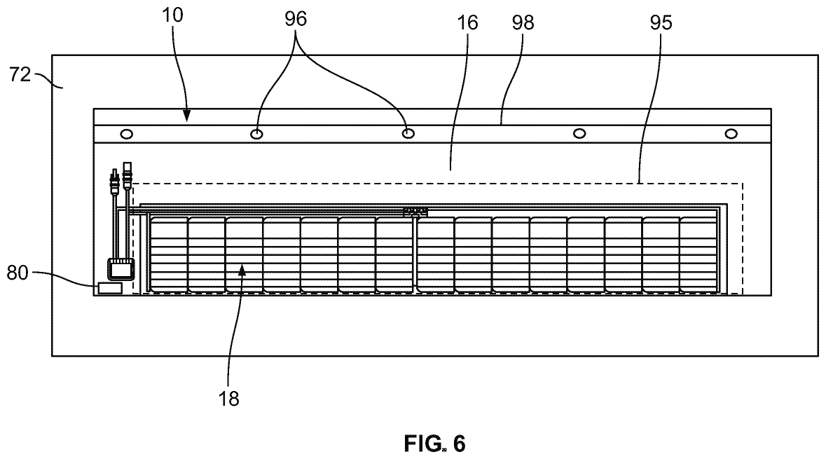

In some embodiments, the plurality of photovoltaic modules 10 is installed directly to the roof deck 72. In some embodiments, the plurality of photovoltaic modules 10 is installed above an underlayment layer installed on the roof deck 72. In some embodiments, the plurality of photovoltaic modules 10 is installed on an underlayment layer installed on the roof deck 72. In some embodiments, each of the plurality of photovoltaic modules 10 is installed on the roof deck 72 by a plurality of fasteners 96 (see FIG. 6). In some embodiments, the plurality of fasteners 96 is installed through the headlap portion 16. In some embodiments, the plurality of fasteners 96 includes a plurality of nails. In some embodiments, the plurality of fasteners 96 includes a plurality of rivets. In some embodiments, the plurality of fasteners 96 includes a plurality of screws. In some embodiments, the plurality of fasteners 96 includes a plurality of staples.

In some embodiments, each of the plurality of photovoltaic modules 10 does not include a frame. In some embodiments, each of the plurality of photovoltaic modules 10 does not include a frame on or around a periphery thereof. In some embodiments, as used herein, the term “frame” means a solar panel frame configured to be installed on one or more side, or all sides, of a periphery of a solar module to seal and fix solar module components thereof, and, in some embodiments, is composed of a metal, such as aluminum or extruded aluminum, or a polymer.

In some embodiments, each of the plurality of photovoltaic modules 10 is installed on the roof deck 72 by an adhesive. In some embodiments, the adhesive is adhered directly to the roof deck 72. In some embodiments, the adhesive is adhered to an underlayment. In some embodiments, the underlayment is adhered directly to the roof deck 72. In some embodiments, the adhesive is located on a rear surface of the photovoltaic module 10. In some embodiments, the adhesive includes at least one adhesive strip. In some embodiments, the adhesive includes a plurality of adhesive strips. In some embodiments, the plurality of adhesive strips is arranged intermittently. In some embodiments, the adhesive is located proximate to at least one edge of the photovoltaic module 10, including the first edge 13 and the second edge 15. In some embodiments, the adhesive is a peel and stick film sheet. In some embodiments, the peel and stick film sheet includes at least one sheet of film removably attached to the inner surface 27. In some embodiments, the peel and stick film sheet is composed of EverGuard Freedom HW peel and stick membrane manufactured by GAF. In some embodiments, the adhesive includes polyvinyl butyrate, acrylic, silicone, or polycarbonate. In some embodiments, the adhesive includes pressure sensitive adhesives.

In some embodiments, the system 70 includes at least one wireway 74 installed proximate to the first ends 12 of the photovoltaic modules 10. In some embodiments, the at least one wireway 74 is installed proximate to the second end 14 of the photovoltaic modules 10. In some embodiments, the at least one wireway 74 is installed intermediate the first end 12 of one of the photovoltaic modules 10 and a second end 14 of another one of the photovoltaic modules 10. In some embodiments, the at least one wireway 74 includes a lid 76. In some embodiments, the lid 76 is removably attached to the at least one wireway 74. In some embodiments, the at least one wireway 74 includes a plurality of the wireways 74. In some embodiments, one of the lids 76 of one of the plurality of wireways 74 overlaps another of the lids 76 of another of the plurality of wireways 74. In some embodiments, the at least one wireway 74 includes a height of 1 mm to 20 mm. In some embodiments, the at least one wireway 74 includes a single wireway installed proximate to the first end of each of the photovoltaic modules 10. In some embodiments, the at least one wireway 74 does not include any electrical components or electrical wires or cables therein. In some embodiments, the at least one wireway 74 and the lids 76 include a structure, composition and/or function of similar to those of more or one of the embodiments of the wireways and lids disclosed in PCT International Patent Publication No. WO 2022/051593, Application No. PCT/US2021/049017, published Mar. 10, 2022, entitled Building Integrated Photovoltaic System, owned by GAF Energy LLC, and U.S. Pat. No. 11,251,744 to Bunea et al., issued Feb. 15, 2022, entitled “Photovoltaic Shingles and Methods of Installing Same,” the contents of each of which are incorporated by reference herein in their entirety. In some embodiments, the at least one wireway 74 and the lids 76 include a structure, composition and/or function of similar to those of more or one of the embodiments of the wireways and wire covers disclosed in attached Appendix A.

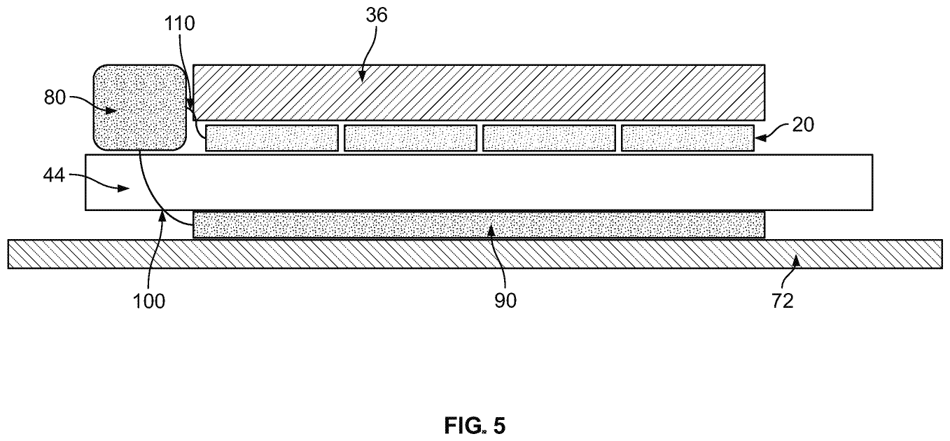

FIG. 5 is a schematic cross-sectional view of the photovoltaic module 10 including an electronics assembly 80 and an energy storage device 90, in accordance with some embodiments of the invention, and as described herein. FIG. 5 shows a representation of the photovoltaic module 10 described above. As shown in the figure, and as discussed, in some embodiments, the photovoltaic module 10 includes the frontsheet 36, one or more of the solar cells 20, and the backsheet 44. In some embodiments, the photovoltaic module 10 includes the electronics assembly 80 and/or the energy storage device 90. As shown in the figure, and as further described, in some embodiments of the invention, the energy storage device 90 is underneath the backsheet 44. In some embodiments, the energy storage device 90 is attached to the second surface (bottom or lower surface) 48 of the backsheet 44. Also as shown in the figure, and as further described, one or more components of the electronics assembly 80 are above the backsheet 44. In some embodiments, one or more components of the electronics assembly 80 are attached to the first surface (top or upper surface) 46 of the backsheet 44. In some embodiments of the invention, one or more components of the electronics assembly 80 are connected to the first side lap 22 and/or the second side lap 24 of the first surface 46. In some embodiments, as shown in the figure, wiring 100 electrically connects the electronics assembly 80 with the energy storage device 90, and wiring 110 electrically connects the electronics assembly 80 with one or more of the solar cells 20. In some embodiments, the electronics assembly 80 is installed within the at least one wireway 74. In some embodiments, the lid 76 overlays the electronics assembly 80.

Referring to FIG. 6, in some embodiments, the electronics assembly 80 and/or the energy storage device 90 are disposed outside of a nail zone 98, such as when the photovoltaic module 10 is a nailable module (that is, a module that is installed on the roof deck 72 by one or more of the fasteners 96 such nails, screws, staples, and/or rivets). In some embodiments, the nail zone 98 is located in at least a portion of the headlap portion 16. In some embodiments, the electronics assembly 80 is installed on the backsheet 44 outside the reveal portion 18 of the photovoltaic module 10. In some embodiments, the energy storage device 90 is installed on the backsheet 44 outside the reveal portion 18 of the photovoltaic module 10. In some embodiments, the energy storage device 90 is installed under the backsheet 44 and at least a portion of the reveal portion 18 of the photovoltaic module 10.

In some embodiments, when the electronics assembly 80 is installed on one of the side laps 22, 24 on the first surface 46 of the backsheet 44, and the energy storage device 90 is installed on the second surface 48 of the backsheet 44, the energy storage device 90 does not overlay or cover either of the side laps 22, 24.

In some embodiments, the energy storage device 90 may comprise at least one capacitor. In some embodiments, the at least one capacitor may comprise a single capacitor. In some embodiments, the at least one capacitor may comprise two capacitors. In some embodiments, the at least one capacitor may comprise three, four, five, six, seven, eight, nine, ten, or more than ten capacitors. In some embodiments, at least one of the capacitors may comprise a super capacitor.

In some embodiments, the energy storage device 90 may comprise at least one battery. In some embodiments, the at least one battery may comprise a single battery. In some embodiments, the at least one battery may comprise two batteries. In some embodiments, the at least one battery may comprise three, four, five, six, seven, eight, nine, ten, or more than ten batteries. In some embodiments, the at least one battery may comprise an electrochemical battery. In some embodiments, some or all the batteries may be wired in series to one or more other batteries. In some embodiments, some or all of the batteries may be wired in parallel to one or more other batteries. In some embodiments, some of the batteries are wired in series to one or more other batteries, and some of the batteries are wired in parallel to one or more other batteries.

In some embodiments, at least one of the batteries may be a lead-acid battery. In some embodiments, at least one of the batteries may be a nickel-cadmium (NiCd) battery. In some embodiments, at least one of the batteries may be a nickel-metal (NiMH) hydride battery. In some embodiments, at least one of the batteries may be a lithium-ion (Li-ion) battery. In some embodiments, at least one of the batteries may be a zinc-ion (ZIB) battery. In some embodiments, at least one of the batteries may be a zinc-air battery. In some embodiments, at least one of the batteries may be a lithium iron phosphate (LFP) battery.

In some embodiments, the energy storage device 90 may be one or more batteries and one or more capacitors.

In some embodiments, the energy storage device 90, such at least one battery and/or at least one capacitor, may be used in place of an external battery, such as a battery disposed in a garage, storage room, or in some other place in a residential, commercial, or industrial building on which the system 70 is installed, and which otherwise stores power generated by the photovoltaic modules 10 of the system 70. In some embodiments, the electronics assembly 80 may be in electrical communication with one or more external batteries, external capacitors, and/or other external energy storage devices—that is, the system 70 may include the energy storage devices 90 of the photovoltaic module 10 as well as one or more external energy storage devices.

In some embodiments, the energy storage device 90 may be configured to be charged with energy produced by one or more of the solar cells 20 of the photovoltaic module 10. In some embodiments, the energy storage device 90 may be configured to be charged with energy produced by one or more of the solar cells 20 of another one of the photovoltaic modules 10 of the system 70, such as through an electrical connection between or among photovoltaic modules 10 of the system 70.

In some embodiments, the electronics assembly 80 may comprise a controller. In some embodiments, the controller may be configured to provide an electrical connection between one or more of the solar cells 20 of the photovoltaic module 10 and the energy storage device 90. In some embodiments, the controller may be configured to control storage of energy produced by one or more of the solar cells 20 of the photovoltaic module 10 in the energy storage device 90. In some embodiments, the controller may be configured to control either or both of charging and/or discharging of the energy storage device 90. In some embodiments, the controller may be configured to control either or both of charging and/or discharging of the energy storage device 90 to regulate the life of the energy storage device 90. In some embodiments, the controller may be configured to control either or both of charging and/or discharging of the energy storage device 90 to regulate energy output. In some embodiments, the electronics assembly 80 may omit a controller.

In some embodiments, whether the electronics assembly 80 does or does not include a controller, the electronics assembly 80 may be in electrical communication with an external controller that is not a part of the electronics assembly 80. In some embodiments, the energy storage device 90 may be in wireless, wired, and/or powerline communication with the external controller, directly or through another component, such as the electronics assembly 80. In some embodiments, the external controller may control charging and/or discharging of the energy storage devices 90 of one or more, or all, of the photovoltaic modules 10 of the system 70, independent of each other. In some embodiments, the external controller may smooth out the generation curve throughout the day, by providing power stored in the energy storage devices 90 when the photovoltaic modules 10 of the system 70 are producing less power. In some embodiments, the external controller may provide power from the energy storage devices 90 of the system 70 at a time or times when energy demand of the electrical system within the structure on which the system 70 is installed increases. In some embodiments, the external controller may provide power from the energy storage devices 90 of the system 70 based on the price of electricity.

In some embodiments, one or more, or all, of the components of the electronics assembly 80 may be underneath the solar cells 20 of the photovoltaic module 10. In some embodiments, one or more, or all, of the components of the electronics assembly 80 may be above the backsheet 44 of the photovoltaic module 10. In some embodiments, one or more, or all, of the components of the electronics assembly 80 may be above the backsheet 44 on either or both of the first side lap 22 and/or the second side lap 24 of the photovoltaic module 10. In some embodiments, when the photovoltaic module 10 includes other electronics, such as the junction box 26 on one of the side laps 22, 24, one or more, or all, of the components of the electronics assembly 80 may be on the other of the side laps 22, 24 of the photovoltaic module 10. In some embodiments, one or more, or all, of the components of the electronics assembly 80 may be underneath the backsheet 44 of the photovoltaic module 10. In some embodiments, one or more, or all, of the components of the electronics assembly 80 may be between the roof deck 72 on which the system 70 is installed, and the photovoltaic module 10. In some embodiments, one or more, or all, of the components of the electronics assembly 80 may be attached to the first surface 46 and/or the second surface 48 of the backsheet 44. In some embodiments, one or more, or all, of the components of the electronics assembly 80 may be attached to the backsheet 44 by one or more mechanical fasteners. In some embodiments, one or more, or all, of the components of the electronics assembly 80 may be attached to the backsheet 44 by thermal bonding. In some embodiments, one or more, or all, of the components of the electronics assembly 80 may be attached to the backsheet 44 by one or more adhesives. In some embodiments, one or more, or all, of the components of the electronics assembly 80 may be attached to the backsheet 44 by welding. In some embodiments, one or more, or all, of the components of the electronics assembly 80 may be attached to the backsheet 44 by heat welding. In some embodiments, one or more, or all, of the components of the electronics assembly 80 may be attached to the backsheet 44 by ultrasonic welding. In some embodiments, one or more, or all, of the components of the electronics assembly 80 may be attached to the backsheet 44 by combinations of one or more mechanical fasteners, thermal bonding, one or more adhesives, welding, heat welding, and/or ultrasonic welding.

In some embodiments, the energy storage device 90 may be underneath the solar cells 20 of the photovoltaic module 10. In some embodiments, the energy storage device 90 may be above the backsheet 44 of the photovoltaic module 10. In some embodiments, the energy storage device 90 may be above the backsheet 44 on either or both of the first side lap 22 and/or the second side lap 24 of the photovoltaic module 10. In some embodiments, the energy storage device 90 may be underneath the backsheet 44 of the photovoltaic module 10. In some embodiments, the energy storage device 90 may be between the roof deck 72 on which the system 70 is installed, and the photovoltaic module 10. In some embodiments, the energy storage device 90 may be attached to the first surface 46 and/or the second surface 48 of the backsheet 44. In some embodiments, the energy storage device 90 may be attached to the backsheet 44 by one or more mechanical fasteners. In some embodiments, the energy storage device 90 may be attached to the backsheet 44 by thermal bonding. In some embodiments, the energy storage device 90 may be attached to the backsheet 44 by one or more adhesives. In some embodiments, the energy storage device 90 may be attached to the backsheet 44 by welding. In some embodiments, the energy storage device 90 may be attached to the backsheet 44 by heat welding. In some embodiments, the energy storage device 90 may be attached to the backsheet 44 by ultrasonic welding. In some embodiments, the energy storage device 90 may be attached to the backsheet 44 by combinations of one or more mechanical fasteners, thermal bonding, one or more adhesives, welding, heat welding, and/or ultrasonic welding.

In some embodiments, when the energy storage device 90 includes at least one battery, the battery may be thin. In some embodiments, the battery may have a thickness of less than 0.2 mm. In some embodiments, the battery may have a thickness of less than 0.3 mm. In some embodiments, the battery may have a thickness of less than 0.4 mm. In some embodiments, the battery may have a thickness of less than 0.5 mm. In some embodiments, the battery may have a thickness of less than 0.6 mm. In some embodiments, the battery may have a thickness of less than 0.7 mm. In some embodiments, the battery may have a thickness of less than 0.8 mm. In some embodiments, the battery may have a thickness of less than 0.9 mm. In some embodiments, the battery may have a thickness of less than 1 mm. In some embodiments, the battery may have a thickness of less than 2 mm. In some embodiments, the battery may have a thickness of less than 3 mm. In some embodiments, the battery may have a thickness of less than 4 mm. In some embodiments, the battery may have a thickness of less than 5 mm. In some embodiments, the battery may have a thickness of less than 6 mm. In some embodiments, the battery may have a thickness of less than 7 mm. In some embodiments, the battery may have a thickness of less than 8 mm. In some embodiments, the battery may have a thickness of less than 9 mm. In some embodiments, the battery may have a thickness of less than 10 mm.

In some embodiments, the battery may have a thickness of 0.2 mm. In some embodiments, the battery may have a thickness of 0.3 mm. In some embodiments, the battery may have a thickness of 0.4 mm. In some embodiments, the battery may have a thickness of 0.5 mm. In some embodiments, the battery may have a thickness of 0.6 mm. In some embodiments, the battery may have a thickness of 0.7 mm. In some embodiments, the battery may have a thickness of 0.8 mm. In some embodiments, the battery may have a thickness of 0.9 mm. In some embodiments, the battery may have a thickness of 1 mm. In some embodiments, the battery may have a thickness of 2 mm. In some embodiments, the battery may have a thickness of 3 mm. In some embodiments, the battery may have a thickness of 4 mm. In some embodiments, the battery may have a thickness of 5 mm. In some embodiments, the battery may have a thickness of 6 mm. In some embodiments, the battery may have a thickness of 7 mm. In some embodiments, the battery may have a thickness of 8 mm. In some embodiments, the battery may have a thickness of 9 mm. In some embodiments, the battery may have a thickness of 10 mm.

In some embodiments, the battery may have a thickness of greater than 0.2 mm. In some embodiments, the battery may have a thickness of greater than 0.3 mm. In some embodiments, the battery may have a thickness of greater than 0.4 mm. In some embodiments, the battery may have a thickness of greater than 0.5 mm. In some embodiments, the battery may have a thickness of greater than 0.6 mm. In some embodiments, the battery may have a thickness of greater than 0.7 mm. In some embodiments, the battery may have a thickness of greater than 0.8 mm. In some embodiments, the battery may have a thickness of greater than 0.9 mm. In some embodiments, the battery may have a thickness of greater than 1 mm. In some embodiments, the battery may have a thickness of greater than 2 mm. In some embodiments, the battery may have a thickness of greater than 3 mm. In some embodiments, the battery may have a thickness of greater than 4 mm. In some embodiments, the battery may have a thickness of greater than 5 mm. In some embodiments, the battery may have a thickness of greater than 6 mm. In some embodiments, the battery may have a thickness of greater than 7 mm. In some embodiments, the battery may have a thickness of greater than 8 mm. In some embodiments, the battery may have a thickness of greater than 9 mm. In some embodiments, the battery may have a thickness of greater than 10 mm.

In some embodiments, the battery may have a thickness of from 0.2 mm to 10 mm. In some embodiments, the battery may have a thickness of from 0.3 mm to 10 mm. In some embodiments, the battery may have a thickness of from 0.4 mm to 10 mm. In some embodiments, the battery may have a thickness of from 0.5 mm to 10 mm. In some embodiments, the battery may have a thickness of from 0.6 mm to 10 mm. In some embodiments, the battery may have a thickness of from 0.7 mm to 10 mm. In some embodiments, the battery may have a thickness of from 0.8 mm to 10 mm. In some embodiments, the battery may have a thickness of from 0.9 mm to 10 mm. In some embodiments, the battery may have a thickness of from 1 mm to 10 mm. In some embodiments, the battery may have a thickness of from 2 mm to 10 mm. In some embodiments, the battery may have a thickness of from 3 mm to 10 mm. In some embodiments, the battery may have a thickness of from 4 mm to 10 mm. In some embodiments, the battery may have a thickness of from 5 mm to 10 mm. In some embodiments, the battery may have a thickness of from 6 mm to 10 mm. In some embodiments, the battery may have a thickness of from 7 mm to 10 mm. In some embodiments, the battery may have a thickness of from 8 mm to 10 mm. In some embodiments, the battery may have a thickness of from 9 mm to 10 mm.

In some embodiments, the battery may have a thickness of from 0.2 mm to 9 mm. In some embodiments, the battery may have a thickness of from 0.3 mm to 9 mm. In some embodiments, the battery may have a thickness of from 0.4 mm to 9 mm. In some embodiments, the battery may have a thickness of from 0.5 mm to 9 mm. In some embodiments, the battery may have a thickness of from 0.6 mm to 9 mm. In some embodiments, the battery may have a thickness of from 0.7 mm to 9 mm. In some embodiments, the battery may have a thickness of from 0.8 mm to 9 mm. In some embodiments, the battery may have a thickness of from 0.9 mm to 9 mm. In some embodiments, the battery may have a thickness of from 1 mm to 9 mm. In some embodiments, the battery may have a thickness of from 2 mm to 9 mm. In some embodiments, the battery may have a thickness of from 3 mm to 9 mm. In some embodiments, the battery may have a thickness of from 4 mm to 9 mm. In some embodiments, the battery may have a thickness of from 5 mm to 9 mm. In some embodiments, the battery may have a thickness of from 6 mm to 9 mm. In some embodiments, the battery may have a thickness of from 7 mm to 9 mm. In some embodiments, the battery may have a thickness of from 8 mm to 9 mm.

In some embodiments, the battery may have a thickness of from 0.2 mm to 8 mm. In some embodiments, the battery may have a thickness of from 0.3 mm to 8 mm. In some embodiments, the battery may have a thickness of from 0.4 mm to 8 mm. In some embodiments, the battery may have a thickness of from 0.5 mm to 8 mm. In some embodiments, the battery may have a thickness of from 0.6 mm to 8 mm. In some embodiments, the battery may have a thickness of from 0.7 mm to 8 mm. In some embodiments, the battery may have a thickness of from 0.8 mm to 8 mm. In some embodiments, the battery may have a thickness of from 0.9 mm to 8 mm. In some embodiments, the battery may have a thickness of from 1 mm to 8 mm. In some embodiments, the battery may have a thickness of from 2 mm to 8 mm. In some embodiments, the battery may have a thickness of from 3 mm to 8 mm. In some embodiments, the battery may have a thickness of from 4 mm to 8 mm. In some embodiments, the battery may have a thickness of from 5 mm to 8 mm. In some embodiments, the battery may have a thickness of from 6 mm to 8 mm. In some embodiments, the battery may have a thickness of from 7 mm to 8 mm.

In some embodiments, the battery may have a thickness of from 0.2 mm to 7 mm. In some embodiments, the battery may have a thickness of from 0.3 mm to 7 mm. In some embodiments, the battery may have a thickness of from 0.4 mm to 7 mm. In some embodiments, the battery may have a thickness of from 0.5 mm to 7 mm. In some embodiments, the battery may have a thickness of from 0.6 mm to 7 mm. In some embodiments, the battery may have a thickness of from 0.7 mm to 7 mm. In some embodiments, the battery may have a thickness of from 0.8 mm to 7 mm. In some embodiments, the battery may have a thickness of from 0.9 mm to 7 mm. In some embodiments, the battery may have a thickness of from 1 mm to 7 mm. In some embodiments, the battery may have a thickness of from 2 mm to 7 mm. In some embodiments, the battery may have a thickness of from 3 mm to 7 mm. In some embodiments, the battery may have a thickness of from 4 mm to 7 mm. In some embodiments, the battery may have a thickness of from 5 mm to 7 mm. In some embodiments, the battery may have a thickness of from 6 mm to 7 mm.

In some embodiments, the battery may have a thickness of from 0.2 mm to 6 mm. In some embodiments, the battery may have a thickness of from 0.3 mm to 6 mm. In some embodiments, the battery may have a thickness of from 0.4 mm to 6 mm. In some embodiments, the battery may have a thickness of from 0.5 mm to 6 mm. In some embodiments, the battery may have a thickness of from 0.6 mm to 6 mm. In some embodiments, the battery may have a thickness of from 0.7 mm to 6 mm. In some embodiments, the battery may have a thickness of from 0.8 mm to 6 mm. In some embodiments, the battery may have a thickness of from 0.9 mm to 6 mm. In some embodiments, the battery may have a thickness of from 1 mm to 6 mm. In some embodiments, the battery may have a thickness of from 2 mm to 6 mm. In some embodiments, the battery may have a thickness of from 3 mm to 6 mm. In some embodiments, the battery may have a thickness of from 4 mm to 6 mm. In some embodiments, the battery may have a thickness of from 5 mm to 6 mm.

In some embodiments, the battery may have a thickness of from 0.2 mm to 5 mm. In some embodiments, the battery may have a thickness of from 0.3 mm to 5 mm. In some embodiments, the battery may have a thickness of from 0.4 mm to 5 mm. In some embodiments, the battery may have a thickness of from 0.5 mm to 5 mm. In some embodiments, the battery may have a thickness of from 0.6 mm to 5 mm. In some embodiments, the battery may have a thickness of from 0.7 mm to 5 mm. In some embodiments, the battery may have a thickness of from 0.8 mm to 5 mm. In some embodiments, the battery may have a thickness of from 0.9 mm to 5 mm. In some embodiments, the battery may have a thickness of from 1 mm to 5 mm. In some embodiments, the battery may have a thickness of from 2 mm to 5 mm. In some embodiments, the battery may have a thickness of from 3 mm to 5 mm. In some embodiments, the battery may have a thickness of from 4 mm to 5 mm.

In some embodiments, the battery may have a thickness of from 0.2 mm to 4 mm. In some embodiments, the battery may have a thickness of from 0.3 mm to 4 mm. In some embodiments, the battery may have a thickness of from 0.4 mm to 4 mm. In some embodiments, the battery may have a thickness of from 0.5 mm to 4 mm. In some embodiments, the battery may have a thickness of from 0.6 mm to 4 mm. In some embodiments, the battery may have a thickness of from 0.7 mm to 4 mm. In some embodiments, the battery may have a thickness of from 0.8 mm to 4 mm. In some embodiments, the battery may have a thickness of from 0.9 mm to 4 mm. In some embodiments, the battery may have a thickness of from 1 mm to 4 mm. In some embodiments, the battery may have a thickness of from 2 mm to 4 mm. In some embodiments, the battery may have a thickness of from 3 mm to 4 mm.

In some embodiments, the battery may have a thickness of from 0.2 mm to 3 mm. In some embodiments, the battery may have a thickness of from 0.3 mm to 3 mm. In some embodiments, the battery may have a thickness of from 0.4 mm to 3 mm. In some embodiments, the battery may have a thickness of from 0.5 mm to 3 mm. In some embodiments, the battery may have a thickness of from 0.6 mm to 3 mm. In some embodiments, the battery may have a thickness of from 0.7 mm to 3 mm. In some embodiments, the battery may have a thickness of from 0.8 mm to 3 mm. In some embodiments, the battery may have a thickness of from 0.9 mm to 3 mm. In some embodiments, the battery may have a thickness of from 1 mm to 3 mm. In some embodiments, the battery may have a thickness of from 2 mm to 3 mm.

In some embodiments, the battery may have a thickness of from 0.2 mm to 2 mm. In some embodiments, the battery may have a thickness of from 0.3 mm to 2 mm. In some embodiments, the battery may have a thickness of from 0.4 mm to 2 mm. In some embodiments, the battery may have a thickness of from 0.5 mm to 2 mm. In some embodiments, the battery may have a thickness of from 0.6 mm to 2 mm. In some embodiments, the battery may have a thickness of from 0.7 mm to 2 mm. In some embodiments, the battery may have a thickness of from 0.8 mm to 2 mm. In some embodiments, the battery may have a thickness of from 0.9 mm to 2 mm. In some embodiments, the battery may have a thickness of from 1 mm to 2 mm.

In some embodiments, the battery may have a thickness of from 0.2 mm to 1 mm. In some embodiments, the battery may have a thickness of from 0.3 mm to 1 mm. In some embodiments, the battery may have a thickness of from 0.4 mm to 1 mm. In some embodiments, the battery may have a thickness of from 0.5 mm to 1 mm. In some embodiments, the battery may have a thickness of from 0.6 mm to 1 mm. In some embodiments, the battery may have a thickness of from 0.7 mm to 1 mm. In some embodiments, the battery may have a thickness of from 0.8 mm to 1 mm. In some embodiments, the battery may have a thickness of from 0.9 mm to 1 mm.

In some embodiments, the battery may have a thickness of from 0.2 mm to 0.9 mm. In some embodiments, the battery may have a thickness of from 0.3 mm to 0.9 mm. In some embodiments, the battery may have a thickness of from 0.4 mm to 0.9 mm. In some embodiments, the battery may have a thickness of from 0.5 mm to 0.9 mm. In some embodiments, the battery may have a thickness of from 0.6 mm to 0.9 mm. In some embodiments, the battery may have a thickness of from 0.7 mm to 0.9 mm. In some embodiments, the battery may have a thickness of from 0.8 mm to 0.9 mm.

In some embodiments, the battery may have a thickness of from 0.2 mm to 0.8 mm. In some embodiments, the battery may have a thickness of from 0.3 mm to 0.8 mm. In some embodiments, the battery may have a thickness of from 0.4 mm to 0.8 mm. In some embodiments, the battery may have a thickness of from 0.5 mm to 0.8 mm. In some embodiments, the battery may have a thickness of from 0.6 mm to 0.8 mm. In some embodiments, the battery may have a thickness of from 0.7 mm to 0.8 mm.

In some embodiments, the battery may have a thickness of from 0.2 mm to 0.7 mm. In some embodiments, the battery may have a thickness of from 0.3 mm to 0.7 mm. In some embodiments, the battery may have a thickness of from 0.4 mm to 0.7 mm. In some embodiments, the battery may have a thickness of from 0.5 mm to 0.7 mm. In some embodiments, the battery may have a thickness of from 0.6 mm to 0.7 mm.

In some embodiments, the battery may have a thickness of from 0.2 mm to 0.6 mm. In some embodiments, the battery may have a thickness of from 0.3 mm to 0.6 mm. In some embodiments, the battery may have a thickness of from 0.4 mm to 0.6 mm. In some embodiments, the battery may have a thickness of from 0.5 mm to 0.6 mm.

In some embodiments, the battery may have a thickness of from 0.2 mm to 0.5 mm. In some embodiments, the battery may have a thickness of from 0.3 mm to 0.5 mm. In some embodiments, the battery may have a thickness of from 0.4 mm to 0.5 mm.

In some embodiments, the battery may have a thickness of from 0.2 mm to 0.4 mm. In some embodiments, the battery may have a thickness of from 0.3 mm to 0.4 mm. In some embodiments, the battery may have a thickness of from 0.2 mm to 0.3 mm.

In some embodiments, the battery may be flat. In some embodiments, the battery may have a flat top surface. In some embodiments, the battery may have a flat bottom surface. In some embodiments, the battery may have flat top and bottom surfaces.

In some embodiments, the electronics assembly 80 may include an inverter. In some embodiments, the inverter may convert DC power produced by the solar cells 20 and/or stored in the energy storage device 90 into AC power that is delivered to the electrical system of the building on which the system 70 is installed.

In some embodiments, the electronics assembly 80 may comprise a DC optimizer. In some embodiments, the DC optimizer may regulate an amount of power produced by the solar cells 20, and/or an amount of power provided to the energy storage device 90.

In some embodiments, the electronics assembly 80 is in electrical communication with an electrical system of the residential, commercial, or industrial building on which the system 70 is installed, such that the power stored in the battery may be used by one or more systems within the building.

In some embodiments, the energy storage device 90 may be connected directly in parallel with one or more of the solar cells 20. In that case, energy storage device 90 may be sized to an appropriate voltage to charge and discharge at or near the maximum power point voltage (Vmp) of the photovoltaic module 10.

In some embodiments, the energy storage device 90 may charge in the morning, and discharging stored energy as light intensity drops because of, e.g., passing clouds and/or reduced sunlight, and energy may be output from the energy storage device 90 to normalize energy output by the system 70 throughout the day.

In some embodiments, the energy storage device 90 may have a capacity of 50 Wh. In some embodiments, the energy storage device 90 may have a capacity of 55 Wh. In some embodiments, the energy storage device 90 may have a capacity of 60 Wh. In some embodiments, the energy storage device 90 may have a capacity of 65 Wh. In some embodiments, the energy storage device 90 may have a capacity of 70 Wh. In some embodiments, the energy storage device 90 may have a capacity of 75 Wh. In some embodiments, the energy storage device 90 may have a capacity of 80 Wh. In some embodiments, the energy storage device 90 may have a capacity of 85 Wh. In some embodiments, the energy storage device 90 may have a capacity of 90 Wh. In some embodiments, the energy storage device 90 may have a capacity of 95 Wh. In some embodiments, the energy storage device 90 may have a capacity of 100 Wh. In some embodiments, the energy storage device 90 may have a capacity of 110 Wh. In some embodiments, the energy storage device 90 may have a capacity of 120 Wh. In some embodiments, the energy storage device 90 may have a capacity of 130 Wh. In some embodiments, the energy storage device 90 may have a capacity of 140 Wh. In some embodiments, the energy storage device 90 may have a capacity of 150 Wh. In some embodiments, the energy storage device 90 may have a capacity of 160 Wh. In some embodiments, the energy storage device 90 may have a capacity of 170 Wh. In some embodiments, the energy storage device 90 may have a capacity of 180 Wh. In some embodiments, the energy storage device 90 may have a capacity of 190 Wh. In some embodiments, the energy storage device 90 may have a capacity of 200 Wh.

In some embodiments, the energy storage device 90 may have a capacity of greater than 50 Wh. In some embodiments, the energy storage device 90 may have a capacity of greater than 55 Wh. In some embodiments, the energy storage device 90 may have a capacity of greater than 60 Wh. In some embodiments, the energy storage device 90 may have a capacity of greater than 65 Wh. In some embodiments, the energy storage device 90 may have a capacity of greater than 70 Wh. In some embodiments, the energy storage device 90 may have a capacity of greater than 75 Wh. In some embodiments, the energy storage device 90 may have a capacity of greater than 80 Wh. In some embodiments, the energy storage device 90 may have a capacity of greater than 85 Wh. In some embodiments, the energy storage device 90 may have a capacity of greater than 90 Wh. In some embodiments, the energy storage device 90 may have a capacity of greater than 95 Wh. In some embodiments, the energy storage device 90 may have a capacity of greater than 100 Wh. In some embodiments, the energy storage device 90 may have a capacity of greater than 110 Wh. In some embodiments, the energy storage device 90 may have a capacity of greater than 120 Wh. In some embodiments, the energy storage device 90 may have a capacity of greater than 130 Wh. In some embodiments, the energy storage device 90 may have a capacity of greater than 140 Wh. In some embodiments, the energy storage device 90 may have a capacity of greater than 150 Wh. In some embodiments, the energy storage device 90 may have a capacity of greater than 160 Wh. In some embodiments, the energy storage device 90 may have a capacity of greater than 170 Wh. In some embodiments, the energy storage device 90 may have a capacity of greater than 180 Wh. In some embodiments, the energy storage device 90 may have a capacity of greater than 190 Wh. In some embodiments, the energy storage device 90 may have a capacity of greater than 200 Wh.

In some embodiments, the energy storage device 90 may have a capacity of less than 50 Wh. In some embodiments, the energy storage device 90 may have a capacity of less than 55 Wh. In some embodiments, the energy storage device 90 may have a capacity of less than 60 Wh. In some embodiments, the energy storage device 90 may have a capacity of less than 65 Wh. In some embodiments, the energy storage device 90 may have a capacity of less than 70 Wh. In some embodiments, the energy storage device 90 may have a capacity of less than 75 Wh. In some embodiments, the energy storage device 90 may have a capacity of less than 80 Wh. In some embodiments, the energy storage device 90 may have a capacity of less than 85 Wh. In some embodiments, the energy storage device 90 may have a capacity of less than 90 Wh. In some embodiments, the energy storage device 90 may have a capacity of less than 95 Wh. In some embodiments, the energy storage device 90 may have a capacity of less than 100 Wh. In some embodiments, the energy storage device 90 may have a capacity of less than 110 Wh. In some embodiments, the energy storage device 90 may have a capacity of less than 120 Wh. In some embodiments, the energy storage device 90 may have a capacity of less than 130 Wh. In some embodiments, the energy storage device 90 may have a capacity of less than 140 Wh. In some embodiments, the energy storage device 90 may have a capacity of less than 150 Wh. In some embodiments, the energy storage device 90 may have a capacity of less than 160 Wh. In some embodiments, the energy storage device 90 may have a capacity of less than 170 Wh. In some embodiments, the energy storage device 90 may have a capacity of less than 180 Wh. In some embodiments, the energy storage device 90 may have a capacity of less than 190 Wh. In some embodiments, the energy storage device 90 may have a capacity of less than 200 Wh.

In some embodiments, the energy storage device 90 may have a capacity of from 50 Wh to 200 Wh. In some embodiments, the energy storage device 90 may have a capacity of from 55 Wh to 200 Wh. In some embodiments, the energy storage device 90 may have a capacity of from 60 Wh to 200 Wh. In some embodiments, the energy storage device 90 may have a capacity of from 65 Wh to 200 Wh. In some embodiments, the energy storage device 90 may have a capacity of from 70 Wh to 200 Wh. In some embodiments, the energy storage device 90 may have a capacity of from 75 Wh to 200 Wh. In some embodiments, the energy storage device 90 may have a capacity of from 80 Wh to 200 Wh. In some embodiments, the energy storage device 90 may have a capacity of from 85 Wh to 200 Wh. In some embodiments, the energy storage device 90 may have a capacity of from 90 Wh to 200 Wh. In some embodiments, the energy storage device 90 may have a capacity of from 95 Wh to 200 Wh. In some embodiments, the energy storage device 90 may have a capacity of from 100 Wh to 200 Wh. In some embodiments, the energy storage device 90 may have a capacity of from 110 Wh to 200 Wh. In some embodiments, the energy storage device 90 may have a capacity of from 120 Wh to 200 Wh. In some embodiments, the energy storage device 90 may have a capacity of from 130 Wh to 200 Wh. In some embodiments, the energy storage device 90 may have a capacity of from 140 Wh to 200 Wh. In some embodiments, the energy storage device 90 may have a capacity of from 150 Wh to 200 Wh. In some embodiments, the energy storage device 90 may have a capacity of from 160 Wh to 200 Wh. In some embodiments, the energy storage device 90 may have a capacity of from 170 Wh to 200 Wh. In some embodiments, the energy storage device 90 may have a capacity of from 180 Wh to 200 Wh. In some embodiments, the energy storage device 90 may have a capacity of from 190 Wh to 200 Wh.

In some embodiments, the energy storage device 90 may have a capacity of from 50 Wh to 190 Wh. In some embodiments, the energy storage device 90 may have a capacity of from 55 Wh to 190 Wh. In some embodiments, the energy storage device 90 may have a capacity of from 60 Wh to 190 Wh. In some embodiments, the energy storage device 90 may have a capacity of from 65 Wh to 190 Wh. In some embodiments, the energy storage device 90 may have a capacity of from 70 Wh to 190 Wh. In some embodiments, the energy storage device 90 may have a capacity of from 75 Wh to 190 Wh. In some embodiments, the energy storage device 90 may have a capacity of from 80 Wh to 190 Wh. In some embodiments, the energy storage device 90 may have a capacity of from 85 Wh to 190 Wh. In some embodiments, the energy storage device 90 may have a capacity of from 90 Wh to 190 Wh. In some embodiments, the energy storage device 90 may have a capacity of from 95 Wh to 190 Wh. In some embodiments, the energy storage device 90 may have a capacity of from 100 Wh to 190 Wh. In some embodiments, the energy storage device 90 may have a capacity of from 110 Wh to 190 Wh. In some embodiments, the energy storage device 90 may have a capacity of from 120 Wh to 190 Wh. In some embodiments, the energy storage device 90 may have a capacity of from 130 Wh to 190 Wh. In some embodiments, the energy storage device 90 may have a capacity of from 140 Wh to 190 Wh. In some embodiments, the energy storage device 90 may have a capacity of from 150 Wh to 190 Wh. In some embodiments, the energy storage device 90 may have a capacity of from 160 Wh to 190 Wh. In some embodiments, the energy storage device 90 may have a capacity of from 170 Wh to 190 Wh. In some embodiments, the energy storage device 90 may have a capacity of from 180 Wh to 190 Wh.

In some embodiments, the energy storage device 90 may have a capacity of from 50 Wh to 180 Wh. In some embodiments, the energy storage device 90 may have a capacity of from 55 Wh to 180 Wh. In some embodiments, the energy storage device 90 may have a capacity of from 60 Wh to 180 Wh. In some embodiments, the energy storage device 90 may have a capacity of from 65 Wh to 180 Wh. In some embodiments, the energy storage device 90 may have a capacity of from 70 Wh to 180 Wh. In some embodiments, the energy storage device 90 may have a capacity of from 75 Wh to 180 Wh. In some embodiments, the energy storage device 90 may have a capacity of from 80 Wh to 180 Wh. In some embodiments, the energy storage device 90 may have a capacity of from 85 Wh to 180 Wh. In some embodiments, the energy storage device 90 may have a capacity of from 90 Wh to 180 Wh. In some embodiments, the energy storage device 90 may have a capacity of from 95 Wh to 180 Wh. In some embodiments, the energy storage device 90 may have a capacity of from 100 Wh to 180 Wh. In some embodiments, the energy storage device 90 may have a capacity of from 110 Wh to 180 Wh. In some embodiments, the energy storage device 90 may have a capacity of from 120 Wh to 180 Wh. In some embodiments, the energy storage device 90 may have a capacity of from 130 Wh to 180 Wh. In some embodiments, the energy storage device 90 may have a capacity of from 140 Wh to 180 Wh. In some embodiments, the energy storage device 90 may have a capacity of from 150 Wh to 180 Wh. In some embodiments, the energy storage device 90 may have a capacity of from 160 Wh to 180 Wh. In some embodiments, the energy storage device 90 may have a capacity of from 170 Wh to 180 Wh.

In some embodiments, the energy storage device 90 may have a capacity of from 50 Wh to 170 Wh. In some embodiments, the energy storage device 90 may have a capacity of from 55 Wh to 170 Wh. In some embodiments, the energy storage device 90 may have a capacity of from 60 Wh to 170 Wh. In some embodiments, the energy storage device 90 may have a capacity of from 65 Wh to 170 Wh. In some embodiments, the energy storage device 90 may have a capacity of from 70 Wh to 170 Wh. In some embodiments, the energy storage device 90 may have a capacity of from 75 Wh to 170 Wh. In some embodiments, the energy storage device 90 may have a capacity of from 80 Wh to 170 Wh. In some embodiments, the energy storage device 90 may have a capacity of from 85 Wh to 170 Wh. In some embodiments, the energy storage device 90 may have a capacity of from 90 Wh to 170 Wh. In some embodiments, the energy storage device 90 may have a capacity of from 95 Wh to 170 Wh. In some embodiments, the energy storage device 90 may have a capacity of from 100 Wh to 170 Wh. In some embodiments, the energy storage device 90 may have a capacity of from 110 Wh to 170 Wh. In some embodiments, the energy storage device 90 may have a capacity of from 120 Wh to 170 Wh. In some embodiments, the energy storage device 90 may have a capacity of from 130 Wh to 170 Wh. In some embodiments, the energy storage device 90 may have a capacity of from 140 Wh to 170 Wh. In some embodiments, the energy storage device 90 may have a capacity of from 150 Wh to 170 Wh. In some embodiments, the energy storage device 90 may have a capacity of from 160 Wh to 170 Wh.

In some embodiments, the energy storage device 90 may have a capacity of from 50 Wh to 160 Wh. In some embodiments, the energy storage device 90 may have a capacity of from 55 Wh to 160 Wh. In some embodiments, the energy storage device 90 may have a capacity of from 60 Wh to 160 Wh. In some embodiments, the energy storage device 90 may have a capacity of from 65 Wh to 160 Wh. In some embodiments, the energy storage device 90 may have a capacity of from 70 Wh to 160 Wh. In some embodiments, the energy storage device 90 may have a capacity of from 75 Wh to 160 Wh. In some embodiments, the energy storage device 90 may have a capacity of from 80 Wh to 160 Wh. In some embodiments, the energy storage device 90 may have a capacity of from 85 Wh to 160 Wh. In some embodiments, the energy storage device 90 may have a capacity of from 90 Wh to 160 Wh. In some embodiments, the energy storage device 90 may have a capacity of from 95 Wh to 160 Wh. In some embodiments, the energy storage device 90 may have a capacity of from 100 Wh to 160 Wh. In some embodiments, the energy storage device 90 may have a capacity of from 110 Wh to 160 Wh. In some embodiments, the energy storage device 90 may have a capacity of from 120 Wh to 160 Wh. In some embodiments, the energy storage device 90 may have a capacity of from 130 Wh to 160 Wh. In some embodiments, the energy storage device 90 may have a capacity of from 140 Wh to 160 Wh. In some embodiments, the energy storage device 90 may have a capacity of from 150 Wh to 160 Wh.

In some embodiments, the energy storage device 90 may have a capacity of from 50 Wh to 150 Wh. In some embodiments, the energy storage device 90 may have a capacity of from 55 Wh to 150 Wh. In some embodiments, the energy storage device 90 may have a capacity of from 60 Wh to 150 Wh. In some embodiments, the energy storage device 90 may have a capacity of from 65 Wh to 150 Wh. In some embodiments, the energy storage device 90 may have a capacity of from 70 Wh to 150 Wh. In some embodiments, the energy storage device 90 may have a capacity of from 75 Wh to 150 Wh. In some embodiments, the energy storage device 90 may have a capacity of from 80 Wh to 150 Wh. In some embodiments, the energy storage device 90 may have a capacity of from 85 Wh to 150 Wh. In some embodiments, the energy storage device 90 may have a capacity of from 90 Wh to 150 Wh. In some embodiments, the energy storage device 90 may have a capacity of from 95 Wh to 150 Wh. In some embodiments, the energy storage device 90 may have a capacity of from 100 Wh to 150 Wh. In some embodiments, the energy storage device 90 may have a capacity of from 110 Wh to 150 Wh. In some embodiments, the energy storage device 90 may have a capacity of from 120 Wh to 150 Wh. In some embodiments, the energy storage device 90 may have a capacity of from 130 Wh to 150 Wh. In some embodiments, the energy storage device 90 may have a capacity of from 140 Wh to 150 Wh.

In some embodiments, the energy storage device 90 may have a capacity of from 50 Wh to 140 Wh. In some embodiments, the energy storage device 90 may have a capacity of from 55 Wh to 140 Wh. In some embodiments, the energy storage device 90 may have a capacity of from 60 Wh to 140 Wh. In some embodiments, the energy storage device 90 may have a capacity of from 65 Wh to 140 Wh. In some embodiments, the energy storage device 90 may have a capacity of from 70 Wh to 140 Wh. In some embodiments, the energy storage device 90 may have a capacity of from 75 Wh to 140 Wh. In some embodiments, the energy storage device 90 may have a capacity of from 80 Wh to 140 Wh. In some embodiments, the energy storage device 90 may have a capacity of from 85 Wh to 140 Wh. In some embodiments, the energy storage device 90 may have a capacity of from 90 Wh to 140 Wh. In some embodiments, the energy storage device 90 may have a capacity of from 95 Wh to 140 Wh. In some embodiments, the energy storage device 90 may have a capacity of from 100 Wh to 140 Wh. In some embodiments, the energy storage device 90 may have a capacity of from 110 Wh to 140 Wh. In some embodiments, the energy storage device 90 may have a capacity of from 120 Wh to 140 Wh. In some embodiments, the energy storage device 90 may have a capacity of from 130 Wh to 140 Wh.

In some embodiments, the energy storage device 90 may have a capacity of from 50 Wh to 130 Wh. In some embodiments, the energy storage device 90 may have a capacity of from 55 Wh to 130 Wh. In some embodiments, the energy storage device 90 may have a capacity of from 60 Wh to 130 Wh. In some embodiments, the energy storage device 90 may have a capacity of from 65 Wh to 130 Wh. In some embodiments, the energy storage device 90 may have a capacity of from 70 Wh to 130 Wh. In some embodiments, the energy storage device 90 may have a capacity of from 75 Wh to 130 Wh. In some embodiments, the energy storage device 90 may have a capacity of from 80 Wh to 130 Wh. In some embodiments, the energy storage device 90 may have a capacity of from 85 Wh to 130 Wh. In some embodiments, the energy storage device 90 may have a capacity of from 90 Wh to 130 Wh. In some embodiments, the energy storage device 90 may have a capacity of from 95 Wh to 130 Wh. In some embodiments, the energy storage device 90 may have a capacity of from 100 Wh to 130 Wh. In some embodiments, the energy storage device 90 may have a capacity of from 110 Wh to 130 Wh. In some embodiments, the energy storage device 90 may have a capacity of from 120 Wh to 130 Wh.

In some embodiments, the energy storage device 90 may have a capacity of from 50 Wh to 120 Wh. In some embodiments, the energy storage device 90 may have a capacity of from 55 Wh to 120 Wh. In some embodiments, the energy storage device 90 may have a capacity of from 60 Wh to 120 Wh. In some embodiments, the energy storage device 90 may have a capacity of from 65 Wh to 120 Wh. In some embodiments, the energy storage device 90 may have a capacity of from 70 Wh to 120 Wh. In some embodiments, the energy storage device 90 may have a capacity of from 75 Wh to 120 Wh. In some embodiments, the energy storage device 90 may have a capacity of from 80 Wh to 120 Wh. In some embodiments, the energy storage device 90 may have a capacity of from 85 Wh to 120 Wh. In some embodiments, the energy storage device 90 may have a capacity of from 90 Wh to 120 Wh. In some embodiments, the energy storage device 90 may have a capacity of from 95 Wh to 120 Wh. In some embodiments, the energy storage device 90 may have a capacity of from 100 Wh to 120 Wh. In some embodiments, the energy storage device 90 may have a capacity of from 110 Wh to 120 Wh.

In some embodiments, the energy storage device 90 may have a capacity of from 50 Wh to 110 Wh. In some embodiments, the energy storage device 90 may have a capacity of from 55 Wh to 110 Wh. In some embodiments, the energy storage device 90 may have a capacity of from 60 Wh to 110 Wh. In some embodiments, the energy storage device 90 may have a capacity of from 65 Wh to 110 Wh. In some embodiments, the energy storage device 90 may have a capacity of from 70 Wh to 110 Wh. In some embodiments, the energy storage device 90 may have a capacity of from 75 Wh to 110 Wh. In some embodiments, the energy storage device 90 may have a capacity of from 80 Wh to 110 Wh. In some embodiments, the energy storage device 90 may have a capacity of from 85 Wh to 110 Wh. In some embodiments, the energy storage device 90 may have a capacity of from 90 Wh to 110 Wh. In some embodiments, the energy storage device 90 may have a capacity of from 95 Wh to 110 Wh. In some embodiments, the energy storage device 90 may have a capacity of from 100 Wh to 110 Wh.

In some embodiments, the energy storage device 90 may have a capacity of from 50 Wh to 100 Wh. In some embodiments, the energy storage device 90 may have a capacity of from 55 Wh to 100 Wh. In some embodiments, the energy storage device 90 may have a capacity of from 60 Wh to 100 Wh. In some embodiments, the energy storage device 90 may have a capacity of from 65 Wh to 100 Wh. In some embodiments, the energy storage device 90 may have a capacity of from 70 Wh to 100 Wh. In some embodiments, the energy storage device 90 may have a capacity of from 75 Wh to 100 Wh. In some embodiments, the energy storage device 90 may have a capacity of from 80 Wh to 100 Wh. In some embodiments, the energy storage device 90 may have a capacity of from 85 Wh to 100 Wh. In some embodiments, the energy storage device 90 may have a capacity of from 90 Wh to 100 Wh. In some embodiments, the energy storage device 90 may have a capacity of from 95 Wh to 100 Wh.

In some embodiments, the energy storage device 90 may have a capacity of from 50 Wh to 95 Wh. In some embodiments, the energy storage device 90 may have a capacity of from 55 Wh to 95 Wh. In some embodiments, the energy storage device 90 may have a capacity of from 60 Wh to 95 Wh. In some embodiments, the energy storage device 90 may have a capacity of from 65 Wh to 95 Wh. In some embodiments, the energy storage device 90 may have a capacity of from 70 Wh to 95 Wh. In some embodiments, the energy storage device 90 may have a capacity of from 75 Wh to 95 Wh. In some embodiments, the energy storage device 90 may have a capacity of from 80 Wh to 95 Wh. In some embodiments, the energy storage device 90 may have a capacity of from 85 Wh to 95 Wh. In some embodiments, the energy storage device 90 may have a capacity of from 90 Wh to 95 Wh.

In some embodiments, the energy storage device 90 may have a capacity of from 50 Wh to 90 Wh. In some embodiments, the energy storage device 90 may have a capacity of from 55 Wh to 90 Wh. In some embodiments, the energy storage device 90 may have a capacity of from 60 Wh to 90 Wh. In some embodiments, the energy storage device 90 may have a capacity of from 65 Wh to 90 Wh. In some embodiments, the energy storage device 90 may have a capacity of from 70 Wh to 90 Wh. In some embodiments, the energy storage device 90 may have a capacity of from 75 Wh to 90 Wh. In some embodiments, the energy storage device 90 may have a capacity of from 80 Wh to 90 Wh. In some embodiments, the energy storage device 90 may have a capacity of from 85 Wh to 90 Wh.

In some embodiments, the energy storage device 90 may have a capacity of from 50 Wh to 85 Wh. In some embodiments, the energy storage device 90 may have a capacity of from 55 Wh to 85 Wh. In some embodiments, the energy storage device 90 may have a capacity of from 60 Wh to 85 Wh. In some embodiments, the energy storage device 90 may have a capacity of from 65 Wh to 85 Wh. In some embodiments, the energy storage device 90 may have a capacity of from 70 Wh to 85 Wh. In some embodiments, the energy storage device 90 may have a capacity of from 75 Wh to 85 Wh. In some embodiments, the energy storage device 90 may have a capacity of from 80 Wh to 85 Wh.

In some embodiments, the energy storage device 90 may have a capacity of from 50 Wh to 80 Wh. In some embodiments, the energy storage device 90 may have a capacity of from 55 Wh to 80 Wh. In some embodiments, the energy storage device 90 may have a capacity of from 60 Wh to 80 Wh. In some embodiments, the energy storage device 90 may have a capacity of from 65 Wh to 80 Wh. In some embodiments, the energy storage device 90 may have a capacity of from 70 Wh to 80 Wh. In some embodiments, the energy storage device 90 may have a capacity of from 75 Wh to 80 Wh.

In some embodiments, the energy storage device 90 may have a capacity of from 50 Wh to 75 Wh. In some embodiments, the energy storage device 90 may have a capacity of from 55 Wh to 75 Wh. In some embodiments, the energy storage device 90 may have a capacity of from 60 Wh to 75 Wh. In some embodiments, the energy storage device 90 may have a capacity of from 65 Wh to 75 Wh. In some embodiments, the energy storage device 90 may have a capacity of from 70 Wh to 75 Wh.

In some embodiments, the energy storage device 90 may have a capacity of from 50 Wh to 70 Wh. In some embodiments, the energy storage device 90 may have a capacity of from 55 Wh to 70 Wh. In some embodiments, the energy storage device 90 may have a capacity of from 60 Wh to 70 Wh. In some embodiments, the energy storage device 90 may have a capacity of from 65 Wh to 70 Wh.

In some embodiments, the energy storage device 90 may have a capacity of from 50 Wh to 65 Wh. In some embodiments, the energy storage device 90 may have a capacity of from 55 Wh to 65 Wh. In some embodiments, the energy storage device 90 may have a capacity of from 60 Wh to 65 Wh.

In some embodiments, the energy storage device 90 may have a capacity of from 50 Wh to 60 Wh. In some embodiments, the energy storage device 90 may have a capacity of from 55 Wh to 60 Wh. In some embodiments, the energy storage device 90 may have a capacity of from 50 Wh to 55 Wh.

In some embodiments, the energy storage device 90 may have a capacity of 250 Wh. In some embodiments, the energy storage device 90 may have a capacity of 300 Wh. In some embodiments, the energy storage device 90 may have a capacity of 350 Wh. In some embodiments, the energy storage device 90 may have a capacity of 400 Wh. In some embodiments, the energy storage device 90 may have a capacity of 450 Wh. In some embodiments, the energy storage device 90 may have a capacity of 500 Wh.

In some embodiments, the energy storage device 90 may have a capacity of from 250 Wh to 500 Wh. In some embodiments, the energy storage device 90 may have a capacity of from 300 Wh to 500 Wh. In some embodiments, the energy storage device 90 may have a capacity of from 350 Wh to 500 Wh. In some embodiments, the energy storage device 90 may have a capacity of from 400 Wh to 500 Wh. In some embodiments, the energy storage device 90 may have a capacity of from 450 Wh to 500 Wh.

In some embodiments, the energy storage device 90 may have a capacity of from 200 Wh to 450 Wh. In some embodiments, the energy storage device 90 may have a capacity of from 250 Wh to 450 Wh. In some embodiments, the energy storage device 90 may have a capacity of from 300 Wh to 450 Wh. In some embodiments, the energy storage device 90 may have a capacity of from 350 Wh to 450 Wh. In some embodiments, the energy storage device 90 may have a capacity of from 400 Wh to 450 Wh.

In some embodiments, the energy storage device 90 may have a capacity of from 200 Wh to 400 Wh. In some embodiments, the energy storage device 90 may have a capacity of from 250 Wh to 400 Wh. In some embodiments, the energy storage device 90 may have a capacity of from 300 Wh to 400 Wh. In some embodiments, the energy storage device 90 may have a capacity of from 350 Wh to 400 Wh.

In some embodiments, the energy storage device 90 may have a capacity of from 200 Wh to 350 Wh. In some embodiments, the energy storage device 90 may have a capacity of from 250 Wh to 350 Wh. In some embodiments, the energy storage device 90 may have a capacity of from 300 Wh to 350 Wh. In some embodiments, the energy storage device 90 may have a capacity of from 200 Wh to 300 Wh. In some embodiments, the energy storage device 90 may have a capacity of from 250 Wh to 300 Wh.

In some embodiments, the system 70 with a plurality of photovoltaic modules 10 may produce from 1 Kw to 100 Kw. In some embodiments, the system 70 may produce 1 Kw. In some embodiments, the system 70 may produce 10 Kw. In some embodiments, the system 70 may produce 20 Kw. In some embodiments, the system 70 may produce 30 Kw. In some embodiments, the system 70 may produce 40 Kw. In some embodiments, the system 70 may produce 50 Kw. In some embodiments, the system 70 may produce 60 Kw. In some embodiments, the system 70 may produce 70 Kw. In some embodiments, the system 70 may produce 80 Kw. In some embodiments, the system 70 may produce 90 Kw. In some embodiments, the system 70 may produce 100 Kw.

In some embodiments, the system 70 may produce more than 1 Kw. In some embodiments, the system 70 may produce more than 10 Kw. In some embodiments, the system 70 may produce more than 20 Kw. In some embodiments, the system 70 may produce more than 30 Kw. In some embodiments, the system 70 may produce more than 40 Kw. In some embodiments, the system 70 may produce more than 50 Kw. In some embodiments, the system 70 may produce more than 60 Kw. In some embodiments, the system 70 may produce more than 70 Kw. In some embodiments, the system 70 may produce more than 80 Kw. In some embodiments, the system 70 may produce more than 90 Kw. In some embodiments, the system 70 may produce more than 100 Kw.

In some embodiments, the system 70 may produce less than 1 Kw. In some embodiments, the system 70 may produce less than 10 Kw. In some embodiments, the system 70 may produce less than 20 Kw. In some embodiments, the system 70 may produce less than 30 Kw. In some embodiments, the system 70 may produce less than 40 Kw. In some embodiments, the system 70 may produce less than 50 Kw. In some embodiments, the system 70 may produce less than 60 Kw. In some embodiments, the system 70 may produce less than 70 Kw. In some embodiments, the system 70 may produce less than 80 Kw. In some embodiments, the system 70 may produce less than 90 Kw. In some embodiments, the system 70 may produce less than 100 Kw.

In some embodiments, the system 70 may produce from 1 Kw to 100 Kw. In some embodiments, the system 70 may produce from 10 Kw to 100 Kw. In some embodiments, the system 70 may produce from 20 Kw to 100 Kw. In some embodiments, the system 70 may produce from 30 Kw to 100 Kw. In some embodiments, the system 70 may produce from 40 Kw to 100 Kw. In some embodiments, the system 70 may produce from 50 Kw to 100 Kw. In some embodiments, the system 70 may produce from 60 Kw to 100 Kw. In some embodiments, the system 70 may produce from 70 Kw to 100 Kw. In some embodiments, the system 70 may produce from 80 Kw to 100 Kw. In some embodiments, the system 70 may produce from 90 Kw to 100 Kw.

In some embodiments, the system 70 may produce from 1 Kw to 90 Kw. In some embodiments, the system 70 may produce from 10 Kw to 90 Kw. In some embodiments, the system 70 may produce from 20 Kw to 90 Kw. In some embodiments, the system 70 may produce from 30 Kw to 90 Kw. In some embodiments, the system 70 may produce from 40 Kw to 90 Kw. In some embodiments, the system 70 may produce from 50 Kw to 90 Kw. In some embodiments, the system 70 may produce from 60 Kw to 90 Kw. In some embodiments, the system 70 may produce from 70 Kw to 90 Kw. In some embodiments, the system 70 may produce from 80 Kw to 90 Kw.

In some embodiments, the system 70 may produce from 1 Kw to 80 Kw. In some embodiments, the system 70 may produce from 10 Kw to 80 Kw. In some embodiments, the system 70 may produce from 20 Kw to 80 Kw. In some embodiments, the system 70 may produce from 30 Kw to 80 Kw. In some embodiments, the system 70 may produce from 40 Kw to 80 Kw. In some embodiments, the system 70 may produce from 50 Kw to 80 Kw. In some embodiments, the system 70 may produce from 60 Kw to 80 Kw. In some embodiments, the system 70 may produce from 70 Kw to 80 Kw.

In some embodiments, the system 70 may produce from 1 Kw to 70 Kw. In some embodiments, the system 70 may produce from 10 Kw to 70 Kw. In some embodiments, the system 70 may produce from 20 Kw to 70 Kw. In some embodiments, the system 70 may produce from 30 Kw to 70 Kw. In some embodiments, the system 70 may produce from 40 Kw to 70 Kw. In some embodiments, the system 70 may produce from 50 Kw to 70 Kw. In some embodiments, the system 70 may produce from 60 Kw to 70 Kw.

In some embodiments, the system 70 may produce from 1 Kw to 60 Kw. In some embodiments, the system 70 may produce from 10 Kw to 60 Kw. In some embodiments, the system 70 may produce from 20 Kw to 60 Kw. In some embodiments, the system 70 may produce from 30 Kw to 60 Kw. In some embodiments, the system 70 may produce from 40 Kw to 60 Kw. In some embodiments, the system 70 may produce from 50 Kw to 60 Kw.

In some embodiments, the system 70 may produce from 1 Kw to 50 Kw. In some embodiments, the system 70 may produce from 10 Kw to 50 Kw. In some embodiments, the system 70 may produce from 20 Kw to 50 Kw. In some embodiments, the system 70 may produce from 30 Kw to 50 Kw. In some embodiments, the system 70 may produce from 40 Kw to 50 Kw.

In some embodiments, the system 70 may produce from 1 Kw to 40 Kw. In some embodiments, the system 70 may produce from 10 Kw to 40 Kw. In some embodiments, the system 70 may produce from 20 Kw to 40 Kw. In some embodiments, the system 70 may produce from 30 Kw to 40 Kw.

In some embodiments, the system 70 may produce from 1 Kw to 30 Kw. In some embodiments, the system 70 may produce from 10 Kw to 30 Kw. In some embodiments, the system 70 may produce from 20 Kw to 30 Kw.

In some embodiments, the system 70 may produce from 1 Kw to 20 Kw. In some embodiments, the system 70 may produce from 10 Kw to 20 Kw. In some embodiments, the system 70 may produce from 1 Kw to 10 Kw.

In some embodiments, one or both of the wiring 100 and/or the wiring 110 may be in the form of one or more individual wires, or bussing. In some embodiments, one or both of the wiring 100 and/or the wiring 110 may be flat ribbon wiring. In some embodiments, one or both of the wiring 100 and/or the wiring 110 may be round wiring. In some embodiments, one or both of the wiring 100 and/or the wiring 110 may be an electrical cable.

In some embodiments, the present invention provides a method, comprising obtaining one or more of the photovoltaic modules 10, and installing the photovoltaic modules 10 above the roof deck 72, such as in an array on the roof deck 72, as shown in FIG. 4. In some embodiments, the method includes electrically connecting the photovoltaic modules 10 to one another; electrically connecting the photovoltaic modules 10 to an electrical component, such as an inverter or an electric panel of a structure.

Variations, modifications and alterations to embodiments of the present disclosure described above will make themselves apparent to those skilled in the art. All such variations, modifications, alterations and the like are intended to fall within the spirit and scope of the present disclosure, limited solely by the appended claims.

While several embodiments of the present disclosure have been described, it is understood that these embodiments are illustrative only, and not restrictive, and that many modifications may become apparent to those of ordinary skill in the art. For example, all dimensions discussed herein are provided as examples only, and are intended to be illustrative and not restrictive.

Any feature or element that is positively identified in this description may also be specifically excluded as a feature or element of an embodiment of the present as defined in the claims.

The disclosure described herein may be practiced in the absence of any element or elements, limitation or limitations, which is not specifically disclosed herein. Thus, for example, in each instance herein, any of the terms “comprising,” “consisting essentially of” and “consisting of” may be replaced with either of the other two terms, without altering their respective meanings as defined herein. The terms and expressions which have been employed are used as terms of description and not of limitation, and there is no intention in the use of such terms and expressions of excluding any equivalents of the features shown and described or portions thereof, but it is recognized that various modifications are possible within the scope of the disclosure.

What is claimed is:

1. A system, comprising:
a plurality of photovoltaic modules installed on a roof deck,
wherein each of the photovoltaic modules includes
at least one solar cell,
an encapsulant encapsulating the at least one solar cell,
wherein the encapsulant includes a first surface and a second surface opposite the first surface,
a frontsheet juxtaposed with the first surface of the encapsulant,
a backsheet juxtaposed with the second surface of the encapsulant,
a headlap portion,
wherein the photovoltaic module is installed on the roof deck by at least one fastener through the headlap portion, and
an energy storage device between the roof deck and the backsheet,
wherein the energy storage device is in electrical communication with the at least one solar cell.

2. The system of claim 1, wherein the energy storage device comprises a battery or a capacitor.

3. The system of claim 1, wherein each of the photovoltaic modules includes an electronics assembly electrically communicating the at least one solar cell with the energy storage device.

4. The system of claim 3, wherein the electronics assembly is on a lower surface of the backsheet.

5. The system of claim 3, wherein the electronics assembly is on an upper surface of the backsheet.

6. The system of claim 3, wherein each of the photovoltaic modules includes a side lap, wherein the side lap includes an upper surface, and wherein the electronics assembly is on the upper surface of the side lap.

7. The system of claim 3, wherein the electronics assembly comprises a controller configured to control at least one of charging of the energy storage device and discharging of the energy storage device.

8. The system of claim 1, wherein the energy storage device has a thickness of 0.2 mm to 10 mm.

9. The system of claim 1, wherein the at least one fastener includes a plurality of fasteners.

10. The system of claim 9, wherein the plurality of fasteners includes one or more of nails, rivets, staples and screws.

11. The system of claim 9, wherein the headlap portion includes a nail zone, and wherein the plurality of fasteners is installed through the nail zone.

12. The system of claim 11, wherein the energy storage device is disposed outside of the nail zone.

13. The system of claim 1, wherein each of the plurality of photovoltaic modules does not include a frame.

14. A photovoltaic module, comprising:
at least one solar cell;
an encapsulant encapsulating the at least one solar cell,
wherein the encapsulant includes a first surface and a second surface opposite the first surface;
a frontsheet juxtaposed with the first surface of the encapsulant;
a backsheet juxtaposed with the second surface of the encapsulant;
a headlap portion;
wherein the photovoltaic module is configured to be installed on a roof deck by at least one fastener through the headlap portion; and
an energy storage device,
wherein the energy storage device is below the backsheet, and
wherein the energy storage device is in electrical communication with the at least one solar cell.

15. The photovoltaic module of claim 14, wherein the energy storage device comprises a battery or a capacitor.

16. The photovoltaic module of claim 14, wherein the energy storage device is attached to a bottom surface of the backsheet.

17. The photovoltaic module of claim 14, further comprising an electronics assembly electrically communicating the at least one solar cell with the energy storage device.

18. The photovoltaic module of claim 17, wherein the electronics assembly is on a bottom surface of the backsheet.

19. The photovoltaic module of claim 17, wherein the electronics assembly is on a top surface of the backsheet.

20. A method, comprising:
obtaining a plurality of photovoltaic modules,
wherein each of the photovoltaic modules includes
at least one solar cell,
an encapsulant encapsulating the at least one solar cell,
wherein the encapsulant includes a first surface and a second surface opposite the first surface,
a frontsheet juxtaposed with the first surface of the encapsulant,
a backsheet juxtaposed with the second surface of the encapsulant, and
a headlap portion, and
an energy storage device,
wherein the energy storage device is located below the backsheet,
wherein the energy storage device is in electrical communication with the at least one solar cell; and
installing the photovoltaic modules on a roof deck,
wherein each of the photovoltaic modules is installed on the roof deck with at least one fastener through the headlap portion, and
wherein the energy storage device is between the roof deck and the backsheet.
